(19) United States
(12) Patent Application Publication
(10) Pub. No.: US 2025/0142937 A1
(43) Pub. Date: May 1, 2025

(54) SEMICONDUCTOR DEVICE AND MANUFACTURING METHOD OF SEMICONDUCTOR DEVICE

(71) Applicant: FUJI ELECTRIC CO., LTD., Kanagawa (JP)

(72) Inventor: Shunsuke TANAKA, Matsumoto-city (JP)

(21) Appl. No.: 18/818,618

(22) Filed: Aug. 29, 2024

(30) Foreign Application Priority Data
Oct. 25, 2023 (JP) 2023-183506

(51) Int. Cl. H01L 29/51; H01L 21/28; H01L 29/423

(52) U.S. Cl. CPC H10D 64/693; H01L 21/28185; H10D 64/516; H10D 64/518; H10D 64/519

(57) ABSTRACT

Provided is a semiconductor device comprising: a semiconductor substrate having an upper surface; a first electrode that is provided on or above the upper surface of the semiconductor substrate; a protective film that is provided on or above the first electrode; a plated layer that is provided on or above the first electrode and has a non-superposed portion that is not overlapped with the protective film in a top view; and a nitride film that is continuously provided from a part between the protective film and the first electrode and a part between the non-superposed portion and the first electrode, wherein a thickness of the plated layer that is positioned upper than the nitride film is greater than a thickness of the nitride film.

### BACKGROUND

### 1. Technical Field

The present invention relates to a semiconductor device and a manufacturing method of the semiconductor device.

### 2. Related Art

Conventionally, a semiconductor device provided with an intermediate layer between an aluminum electrode and organic protective film is known (refer to Patent document 1). In addition, a semiconductor device with a triple point at which end portions of a protective film, a plated layer and an emitter electrode overlap each other does not exist is known (refer to Patent document 2).
Patent Document 1: WO 2017/103978
Patent document 2: Japanese Patent Application Publication No. 2017-168659

### BRIEF DESCRIPTION OF THE DRAWINGS

FIG. 1 illustrates a top view showing an example of a semiconductor device 100 according to one embodiment of the present invention.

FIG. 2A is a figure showing an example of a cross section taken along a-a in FIG. 1.

FIG. 2B shows another example of the cross section taken along a-a in FIG. 1.

FIG. 3A shows an example of the cross section taken along a-a in a comparative example.

FIG. 3B shows another example of the cross section taken along a-a in a comparative example.

FIG. 4 shows another example of the cross section taken along a-a in FIG. 1.

FIG. 5 shows a part of the manufacturing process of the semiconductor device 100.

FIG. 6 shows another example of the cross section taken along a-a in FIG. 1.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are imperative to the solutions of the invention.

In the present specification, one side in a direction parallel to a depth direction of a semiconductor substrate is referred to as “upper” and another side is referred to as “lower”. One surface of two principal surfaces of a substrate, a layer or other members is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicate the height direction with respect to the ground. Note that the +Z axis direction and the −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including the X axis direction and the Y axis direction.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type or a semiconductor presenting a conductivity type of the P type.

In the present specification, a description of a P+ type or an N+ type means a higher doping concentration than that of the P type or the N type, and a description of a P− type or an N− type means a lower doping concentration than that of the P type or the N type.

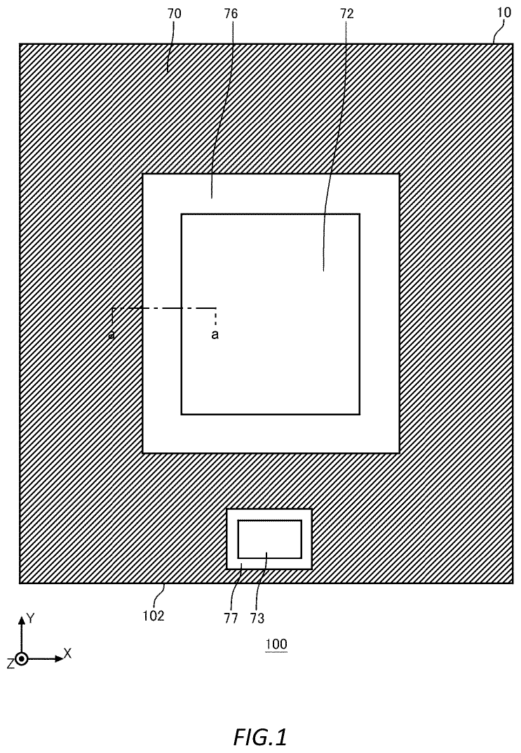

FIG. 1 illustrates a top view showing an example of a semiconductor device 100 according to one embodiment of the present invention. The semiconductor device 100 includes a semiconductor substrate 10, a protective film 70, a plated layer 72, and a nitride film 76. The semiconductor device 100 may further include a plated layer 73 and a nitride film 77. The semiconductor substrate 10 has an upper surface and a lower surface. FIG. 1 shows a figure of the semiconductor device 100 seen from above the upper surface of the semiconductor substrate 10, and this is referred to as a top view in the present specification.

The semiconductor substrate 10 is a substrate that is formed of a semiconductor material. As an example, the semiconductor substrate 10 is a silicon substrate. The semiconductor substrate 10 has an end side 102 in a top view. The semiconductor substrate 10 of the present example includes two sets of end sides 102 facing each other in the top view. In FIG. 1, the X axis and the Y axis are parallel to any of the end sides 102. In addition, the Z axis is perpendicular to the upper surface of the semiconductor substrate 10.

The semiconductor substrate 10 is provided with at least one of a transistor portion or a diode portion described below. A first electrode described below is provided on or above the upper surface of the semiconductor substrate 10. The first electrode may be an Al—Si alloy, as an example. The first electrode is an electrode at which a main current flows, such as an emitter electrode, a source electrode, or the like. The protective film 70, the plated layer 72, and the nitride film 76 of the present example is provided on or above the first electrode. A solder is provided on or above the protective film 70, the plated layer 72, and the nitride film 76, and for example, connected to a lead frame that is bonded with the solder via an external power supply and the like, but this is omitted in FIG. 1.

A control electrode such as a gate pad may be provided on or above the upper surface of the semiconductor substrate 10. The protective film 70 of the present example is also provided on or above the control electrode. The plated layer 73 and the nitride film 77 are provided on or above the control electrode. The arrangement and the structure of the protective film 70, the plated layer 73, and the nitride film 77 on or above the control electrode is similar to the arrangement and the structure of the protective film 70, the plated layer 72, and the nitride film 76 on or above the first electrode. In the present specification, the arrangement and the structure of the protective film 70, the plated layer 72, and the nitride film 76 on or above the first electrode is described, but description of the arrangement and the structure of the protective film 70, the plated layer 73, and the nitride film 77 on or above the control electrode is omitted. The nitride film 77 may be connected to the nitride film 76. That is, the nitride film 77 may be a part of the nitride film 76.

On or above the semiconductor substrate 10, an electrode other than the first electrode and the control electrode may be further provided. For each electrode on or above the semiconductor substrate 10, a structure that is similar to that of the protective film 70, the plated layer 72, and the nitride film 76 may be provided.

The protective film 70 is provided from the end side 102 of the semiconductor substrate 10 toward the inside of the semiconductor substrate 10 in a top view. In FIG. 1, the portion provided with the protective film 70 is hatched. The protective film 70 is an organic film with insulating property, and is a polyimide, for an example. On or above the first electrode, an aperture is provided inside the protective film 70. On or above the first electrode on the aperture, the plated layer 72 and the nitride film 76 are provided, and exposed upward from the aperture of the protective film 70.

The plated layer 72 is provided inside the semiconductor substrate 10 than the protective film 70. That is, the plated layer 72 is provided in the aperture of the protective film 70. Note that the protective film 70 and the plated layer 72 may be overlapped. A portion that is not overlapped with the protective film 70 in a top view is referred to as a non-superposed portion. That is, the plated layer 72 has a non-superposed portion. The plated layer 72 is electrically connected to the first electrode. The plated layer 72 may be nickel, or may be a structure with gold stacked on the nickel for preventing oxidizing.

The nitride film 76 is continuously provided from a part between the protective film 70 and the first electrode to a part between the non-superposed portion in the plated layer 72 and the first electrode. The nitride film 76 may be overlapped with the entire protective film 70. The nitride film 76 in the present example has a portion that is not overlapped with the protective film 70. The nitride film 76 may be provided in a range that is wider than the protective film 70 in a top view. Because the protective film 70 and the plated layer 72 of the present example do not overlap, the nitride film 76 between the protective film 70 and the plated layer 72 is exposed upward. The nitride film 76 may be a silicon nitride with a good adhesiveness with Al—Si.

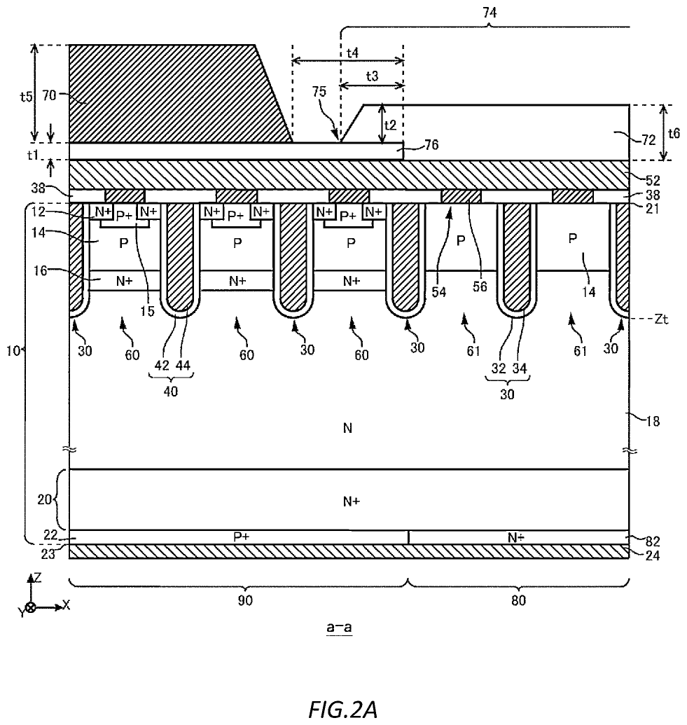

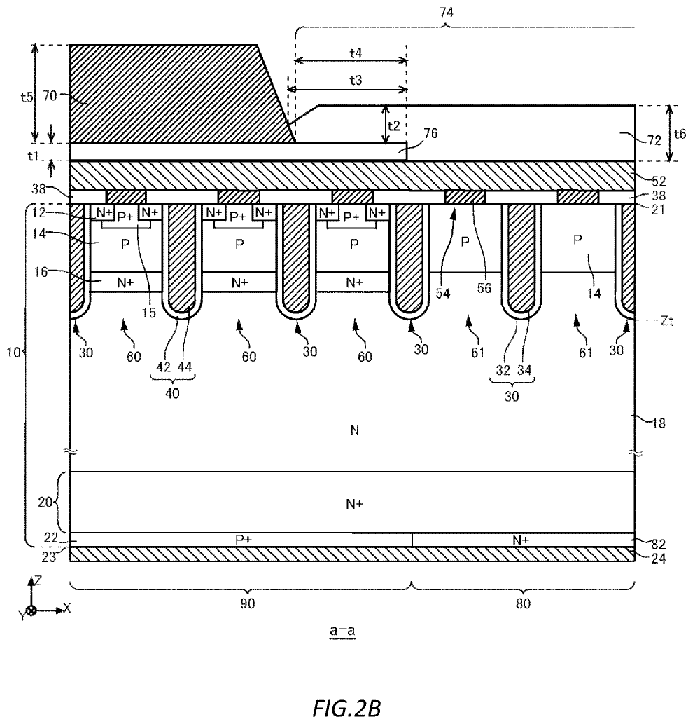

FIG. 2A is a figure showing an example of a cross section taken along a-a in FIG. 1. The cross section taken along a-a of the present example is an XZ cross section passing through a semiconductor substrate 10, an emitter electrode 52, a collector electrode 24, an interlayer dielectric film 38, a protective film 70, a plated layer 72, and a nitride film 76. The semiconductor device 100 of the present example has the semiconductor substrate 10, the interlayer dielectric film 38, the emitter electrode 52, the collector electrode 24, the protective film 70, the plated layer 72, and the nitride film 76 in the cross section.

The semiconductor substrate 10 has an upper surface 21 and a lower surface 23. The semiconductor substrate 10 of the present example is described as an RC-IGBT having a transistor portion 90 and a diode portion 80, but is not limited thereto. The transistor portion 90 may be a MOSFET. The semiconductor substrate 10 may have the transistor portion 90 only or may have the diode portion 80 only. In addition, the cross section taken along a-a may be a cross section with a pad portion described below such as a gate pad and the like for applying a gate voltage to a gate trench portion formed thereto.

The interlayer dielectric film 38 is provided on the upper surface 21 of the semiconductor substrate 10. The interlayer dielectric film 38 is a film including at least one layer of a dielectric film such as silicate glass to which an impurity such as boron or phosphorous is added, a thermal oxide film, and other dielectric films. The interlayer dielectric film 38 is provided with a contact hole 54. Inside the contact hole 54, a contact plug 56 formed of tungsten or the like is filled.

The emitter electrode 52 is provided on or above the interlayer dielectric film 38. The emitter electrode 52 is in contact with the upper surface 21 of the semiconductor substrate 10 via the contact plug 56. The emitter electrode 52 is an example of the first electrode. The collector electrode 24 is provided on a lower surface 23 of the semiconductor substrate 10. The emitter electrode 52 and the collector electrode 24 are formed of a metal material such as aluminum. In the present specification, the direction in which the emitter electrode 52 is connected to the collector electrode 24 (the Z axis direction) is referred to as a depth direction.

The semiconductor substrate 10 includes an N type drift region 18. The drift region 18 is provided in each of a transistor portion 90 and a diode portion 80.

Each of the transistor portion 90 and the diode portion 80 has a plurality of trench portions arrayed in the array direction (X axis direction). In the transistor portion 90 in the present example, one or more gate trench portions 40 and one or more dummy trench portions 30 are alternately provided along the array direction. In the diode portion 80 in the present example, the plurality of dummy trench portions 30 are provided along the array direction. In the diode portion 80 in the present example, the gate trench portion 40 is not provided.

A mesa portion is provided between respective trench portions in the array direction. The mesa portion refers to a region sandwiched between the trench portions inside the semiconductor substrate 10. As an example, the upper end of the mesa portion is the upper surface 21 of the semiconductor substrate 10. The depth position of the lower end of the mesa portion is the same as the depth position of the lower end of the trench portion. The mesa portion of the present example is provided extending in the extending direction (the Y axis direction) along the trench portion, on the upper surface 21 of the semiconductor substrate 10. In the present example, mesa portions 60 are provided in the transistor portion 90, and mesa portions 61 are provided in the diode portion 80.

In a case of simply mentioning “mesa portion” in the present specification, the portion refers to each of a mesa portion 60 and a mesa portion 61.

In the mesa portion 60 of the transistor portion 90, an emitter region 12 of an N+ type, a contact region 15 of a P+ type, and a base region 14 of a P type are provided on the upper surface 21 side of the semiconductor substrate 10. A drift region 18 of an N type is provided below the base region 14. In the mesa portion 60, an accumulation region 16 of the N+ type is provided. The accumulation region 16 is arranged between the base region 14 and the drift region 18.

The emitter region 12 is exposed on the upper surface 21 of the semiconductor substrate 10 and is provided in contact with a gate trench portion 40. The emitter region 12 may be in contact with the trench portions on both sides of the mesa portion 60. The emitter region 12 has a higher doping concentration than the drift region 18.

The contact region 15 is exposed to the upper surface 21 of the semiconductor substrate 10 in the center of the mesa portion 60 than the emitter region 12. The contact region 15 may be provided deeper than the emitter region 12.

The base region 14 is provided below the emitter region 12 and the contact region 15. The base region 14 is provided to be in contact with the emitter region 12 and the contact region 15. The base region 14 may be in contact with the trench portions on both sides of the mesa portion 60.

The accumulation region 16 is provided below the base region 14. The accumulation region 16 is a region of the N+ type having a higher doping concentration than the drift region 18. Providing the accumulation region 16 having a high concentration between the drift region 18 and the base region 14 can increase a carrier implantation enhancement effect (IE effect) and reduce an on-voltage. The accumulation region 16 may be provided so as to cover the entire lower surface of the base region 14 in each mesa portion 60.

The mesa portion 61 of the diode portion 80 is provided with the P type of base region 14 in contact with the upper surface 21 of the semiconductor substrate 10. The drift region 18 is provided below the base region 14. In the mesa portion 61, the accumulation region 16 may be provided below the base region 14.

In each of the transistor portion 90 and the diode portion 80, an N+ type buffer region 20 may be provided below the drift region 18. The doping concentration of the buffer region 20 is higher than the doping concentration of the drift region 18. The buffer region 20 may function as a field stopper layer which prevents a depletion layer expanding from the lower end of the base region 14 from reaching the collector region 22 of a P+ type and the cathode region 82 of the N+ type.

In the transistor portion 90, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration in the cathode region 82 is higher than a donor concentration in the drift region 18. A donor of the cathode region 82 is, for example, hydrogen or phosphorous. It should be noted that an element serving as a donor and an acceptor in each region is not limited to the example described above. The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum. The boundary in the X axis direction between the diode portion 80 and the transistor portion 90 in the present example is the boundary between the cathode region 82 and the collector region 22.

Each trench portion penetrates the base region 14 from the upper surface 21 of the semiconductor substrate 10, and reaches the drift region 18. In a region where at least any of the emitter region 12, the contact region 15, and the accumulation region 16 is provided, each trench portion also penetrates through these doping regions to reach the drift region 18. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

The gate trench portion 40 has a gate trench provided at the upper surface 21 of the semiconductor substrate 10, a gate dielectric film 42, and a gate conductive portion 44. The gate dielectric film 42 is provided covering the inner wall of the gate trench. The gate dielectric film 42 may be formed by oxidizing or nitriding a semiconductor on the inner wall of the gate trench. The gate conductive portion 44 is provided farther inward than the gate dielectric film 42 in the gate trench. In other words, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to a gate runner in another cross section. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 may be electrically connected to the emitter electrode 52 in another cross section. The dummy dielectric film 32 is provided covering an inner wall of the dummy trench. The dummy conductive portion 34 is provided in the dummy trench, and is provided farther inward than the dummy dielectric film 32. The dummy dielectric film 32 insulates the dummy conductive portion 34 from the semiconductor substrate 10. The dummy conductive portion 34 may be formed of the same material as that of the gate conductive portion 44. For example, the dummy conductive portion 34 is formed of a conductive material such as polysilicon. The dummy conductive portion 34 may have the same length as that of the gate conductive portion 44 in the depth direction.

The gate trench portions 40 and the dummy trench portions 30 in the present example are covered with the interlayer dielectric film 38 on the upper surface 21 of the semiconductor substrate 10. It should be noted that bottom portions of the dummy trench portion 30 and the gate trench portion 40 may be formed in a curved-surface shape (a curved-line shape in the cross section) convexly downward.

The protective film 70, the plated layer 72, and the nitride film 76 are provided on or above the emitter electrode 52. A solder is formed on or above the plated layer 72, but is omitted in FIG. 2A. The solder may be also formed on or above the protective film 70 and the nitride film 76. The plated layer 72 has a non-superposed portion 74 that does not overlap with the protective film 70 in a depth direction (Z axis direction). Because the protective film 70 and the plated layer 72 of the present example are apart from each other, the entire plated layer 72 is the non-superposed portion 74.

The nitride film 76 is provided between the protective film 70 and the emitter electrode 52. The nitride film 76 of the present example is in contact with the emitter electrode 52. The nitride film 76 is continuously provided from a part between the protective film 70 and the emitter electrode 52 to a part between the non-superposed portion 74 in the plated layer 72 and the emitter electrode 52. By providing the nitride film 76, the solder can be prevented from reaching a triple point of the emitter electrode 52, the protective film 70, and the plated layer 72 described below.

A thickness of the nitride film 76 in the depth direction is referred to as t1. The thickness t1 of the nitride film 76 may be an average value of thickness in the entire nitride film 76, or may be an average value of a thickness of a portion in the nitride film 76 that overlaps with the protective film 70. In the depth direction, a thickness of the plated layer 72 that is positioned upper than the nitride film 76 is referred to as t2. The thickness t2 may be greater than the thickness t1. By relatively reducing the thickness t1, unevenness of the plated layer 72 due to the nitride film 76 being provided can be reduced. The thickness t2 may be 1.5 times or more, twice or more, three times or more, or 5 times or more of the thickness t1. The thickness t2 may be 10 times or less of the thickness t1. The plated layer 72 that is positioned upper than the nitride film 76 includes a portion that does not overlap with the nitride film 76 in the depth direction. In that case, the thickness t2 may be a thickness of the plated layer 72 that is positioned upper than a position of the upper end of the nitride film 76 being extended to a plane that is parallel to the upper surface 21. The thickness t2 may be a value in the center of the plated layer 72, may be an average value of a thickness of the entire plated layer 72, or may be an average value or the maximum value of the thickness of the portion that overlaps with the nitride film 76.

The nitride film 76 may be in contact with the plated layer 72. The nitride film 76 may be overlapped with the plated layer 72. In a top view, a length of a portion in which the nitride film 76 and the plated layer 72 are overlapped, the length taken in a direction that is perpendicular to an end side 75 of the plated layer 72, is referred to as t3. The end side 75 represented in FIG. 2A extends in a Y axis direction. In FIG. 2A, the length t3 is a length in an X axis direction, but in a portion in which an end side of the plated layer 72 is extended in the X axis direction, the length t3 is a length in the Y axis direction. The length t3 may be 1 μm or more. As a result, the solder can be prevented from reaching the emitter electrode 52.

In a case in which the solder is formed on the plated layer 72, an event in which a portion of about 2 μm from a surface of the plated layer 72 reacts with the solder, i.e., a so-called solder leaching may occur. Therefore, the length t3 may be 2 μm or more, or may be 2.5 μm or more. As a result, the solder can be prevented from reaching the emitter electrode 52. The length t3 may be 5 μm or less, 4 μm or less, or 3.5 μm or less. In addition, the length t3 may be less than a thickness t6 of the plated layer 72 and may be equal to the thickness t6 of the plated layer 72.

In the nitride film 76, a length of a portion that protrudes toward a side of the plated layer 72 from the protective film 70 is referred to as t4. Similar to the case of the length t3, in FIG. 2A, the length t4 is a length in the X axis direction, but in a portion in which the end side of the protective film 70 is extending to the X axis direction, the length t4 is referred to as a length of the Y axis direction. The length t4 may be a length in a direction that is perpendicular to the end side of the protective film 70 in a top view. The length t4 may be 3 μm or more, or may be 4 μm or more. The length t4 may be 5 μm or less, or may be 7 μm or less.

FIG. 2B shows another example of the cross section taken along a-a in FIG. 1. The arrangement of the protective film 70 and the plated layer 72 in the cross section taken along a-a of the present example is different from that of the cross section taken along a-a represented in FIG. 2A. Descriptions of the other places are omitted because they are the same as those of FIG. 2A.

The protective film 70 and the plated layer 72 in the present example are in contact with each other. An end portion of the plated layer 72 may be arranged on or above an end portion of the protective film 70. Because adhesiveness between the protective film 70 and the plated layer 72 is not high as described below, the solder may infiltrate between the protective film 70 and the plated layer 72. In the present example, the solder can be prevented from reaching the emitter electrode 52 (that is, the triple point) at which the solder is infiltrated between the protective film 70 and the plated layer 72 due to the provision of the nitride film 76.

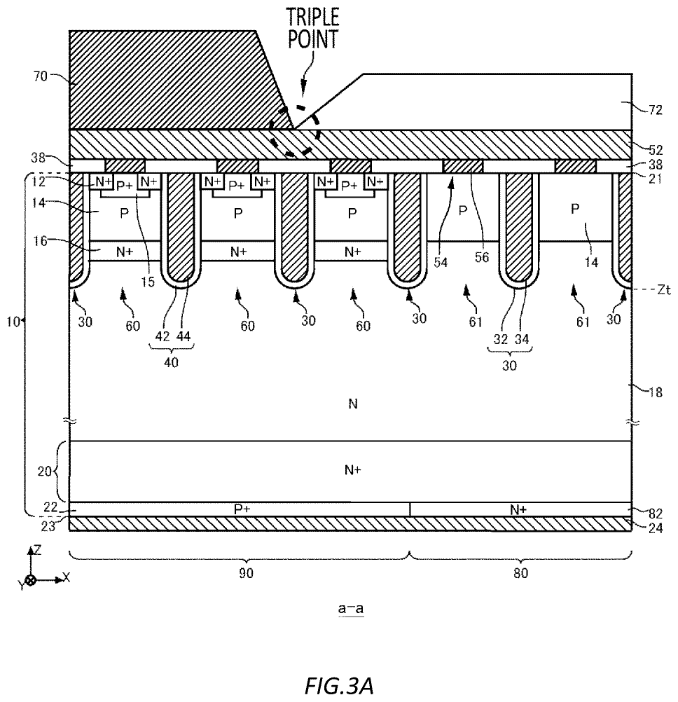

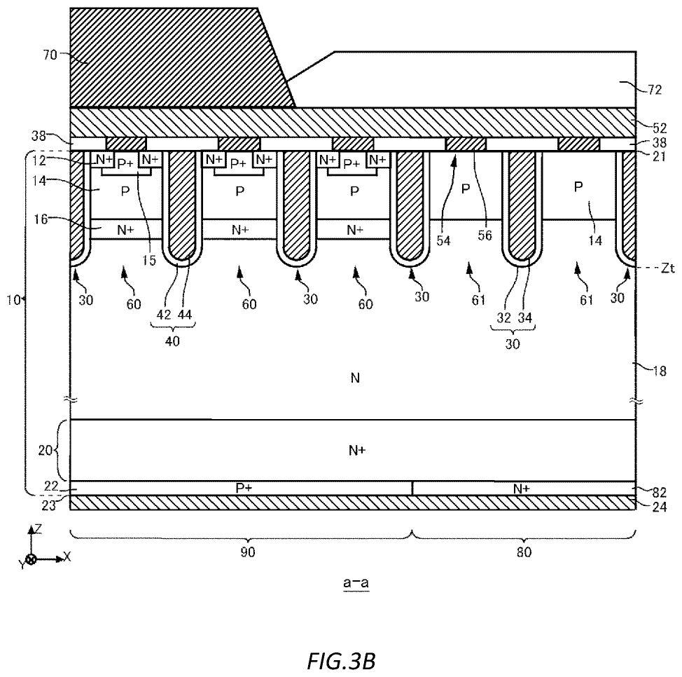

FIG. 3A shows an example of the cross section taken along a-a in a comparative example. A semiconductor device 100 of the present example does not include a nitride film 76. Descriptions of the other places are omitted because they are the same as those of FIG. 2A. Near an end side of an aperture of a protective film 70, a residue of an organic matter that occurs upon patterning and etching of the protective film 70 easily remains, if a plating process for forming a plated layer 72 is performed under that state, a plating is less likely to grow near the end side of the aperture of the protective film 70, and therefore the plated layer 72 may not be formed. Therefore, the triple point of the emitter electrode 52, the protective film 70, the plated layer 72 is formed and exposed upward. The triple point of the present specification means a position in which the emitter electrode 52, the protective film 70, and the plated layer 72 coexist. If a subsequent operation proceeds under this state and the solder is formed, the solder reaches the above-described triple point.

Under the state in which the solder reaches the triple point, if the semiconductor device 100 is used for a long time, a crack progresses in the order of the emitter electrode 52 and the semiconductor substrate 10. By progressing of the crack, reliability against a failure and the like of the semiconductor device 100 falls down. The progressing of the crack gradually proceeds by using for a long time, and therefore it is difficult to detect it in an inspection before shipping.

Because the semiconductor device 100 of the present embodiment has a nitride film 76 continuously provided from a part between the protective film 70 and the emitter electrode 52 to a part between the non-superposed portion 74 of the plated layer 72 and the emitter electrode 52 as represented in FIG. 2A and FIG. 2B, the above-described triple point is not formed. In addition, the solder also can be prevented from reaching the emitter electrode 52.

FIG. 3B shows another example of the cross section taken along a-a in a comparative example. A semiconductor device 100 of the present example also does not include a nitride film 76. Descriptions of the other places are omitted because they are the same as those of FIG. 2A. The present example indicates a case in which a residue of organic matter does not remain near an end side of an aperture of the protective film 70, and the plating also has grown near the end side of the aperture of the protective film 70. In this case the triple point is formed, but it is not exposed upward. However, because adhesiveness between the protective film 70 and the plated layer 72 is not high, it is concerned that the solder infiltrates between the protective film 70 and the plated layer 72 and reaches the triple point. Because the triple point is not formed by virtue of the nitride film 76 in the semiconductor device 100 of the present embodiment, even if the plating has grown near the end side of the aperture of the protective film 70, falling down of the reliability of the semiconductor device 100 can be suppressed.

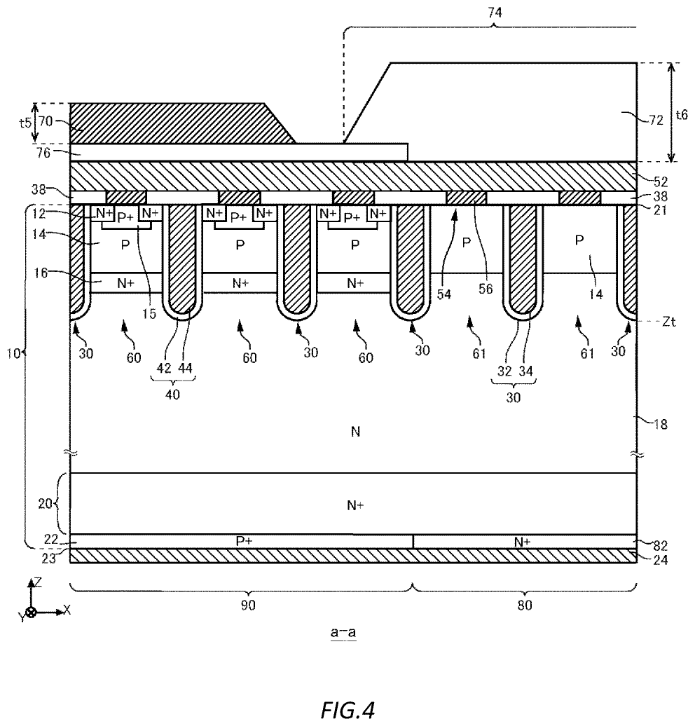

FIG. 4 shows another example of the cross section taken along a-a in FIG. 1. The thicknesses of the protective film 70 and the plated layer 72 in the cross section taken along a-a of the present example is different from those of the cross section taken along a-a represented in FIG. 2A. Descriptions of the other places are omitted because they are the same as those of FIG. 2A.

A thickness of the protective film 70 in the depth direction is referred to as t5. A thickness of the plated layer 72 in the depth direction is referred to as t6. In the semiconductor device 100 of the present example, the thickness t6 is greater than the thickness t5. By increasing the thickness of the plated layer 72, unevenness of the plated layer 72 due to the nitride film 76 being provided can be reduced. Note that, as represented in FIG. 2A or the like, the thickness t5 may be greater than the thickness t6. In addition, in the present example, the protective film 70 and the plated layer 72 may be in contact with each other, as represented in FIG. 2B.

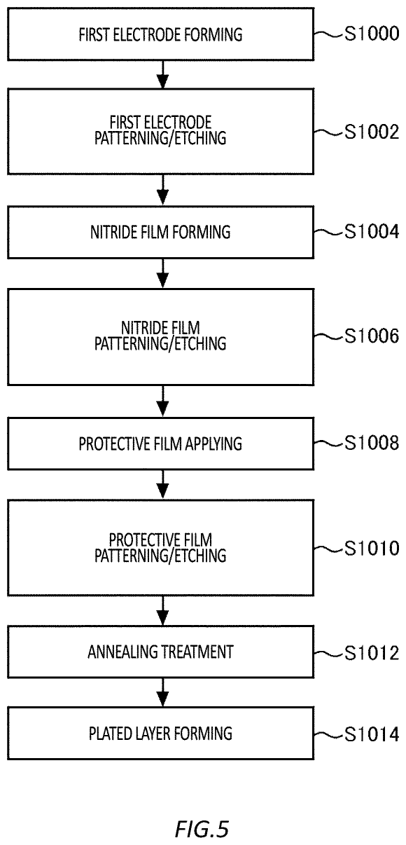

FIG. 5 shows a part of the manufacturing process of the semiconductor device 100. The manufacturing process of the present example has a first electrode forming step S1000, a first electrode patterning/etching step S1002, a nitride film forming step S1004, a nitride film patterning/etching step S1006, a protective film applying step S1008, a protective film patterning/etching step S1010, an annealing treatment step S1012, and a plated layer forming step S1014.

In the first electrode forming step S1000, a first electrode is formed on or above an upper surface 21 of the semiconductor substrate 10. In the semiconductor substrate 10, an element structure represented in FIG. 2A or the like as an example is formed. The first electrode is an emitter electrode 52 as an example, and may be an Al—Si alloy. In the first electrode patterning/etching step S1002, the first electrode that has been formed is patterned and etched to be a desired shape.

In the nitride film forming step S1004, the nitride film 76 is formed on a part of the first electrode. The nitride film 76 is a silicon nitride as an example, and is formed by a method such as sputtering. In the nitride film patterning/etching step S1006, the nitride film 76 that has been formed is patterned and etched to form an aperture.

In the protective film applying step S1008, the protective film 70 is formed on or above a part of the nitride film 76. The protective film 70 may be an organic film with insulating property, and is a polyimide, for an example. In the protective film patterning/etching step S1010, the protective film 70 is patterned and etched to form an aperture. At this time, by making the aperture of the protective film 70 be greater than the aperture of the nitride film 76, the nitride film 76 can be continuously provided to a part between the non-superposed portion 74 of the plated layer 72 that is to be subsequently formed and the first electrode, as represented in FIG. 2A or the like.

In the annealing treatment step S1012, an annealing treatment is performed on the nitride film 76 and the protective film 70. As a result, adhesiveness between the protective film 70 and the nitride film 76 can be improved, and growing of a second plated layer described below can be suppressed. A temperature of the annealing treatment is 300° C. or more and 400° C. or less, as an example. A duration of annealing treatment is 30 minutes or more and one hour or less, as an example. The duration of the annealing treatment may be 40 minutes or more, or may be 50 minutes or less.

In the plated layer forming step S1014, after the annealing treatment step S1012, the plated layer 72 is formed on or above a part of the first electrode that is not covered by the nitride film 76 and on or above a part of the nitride film 76. The plated layer 72 may be nickel, and is formed by a method such as an electroless plating. A gold film for preventing oxidizing may be formed on the nickel. Subsequently, a solder is formed on the protective film 70, the nitride film 76, and the plated layer 72.

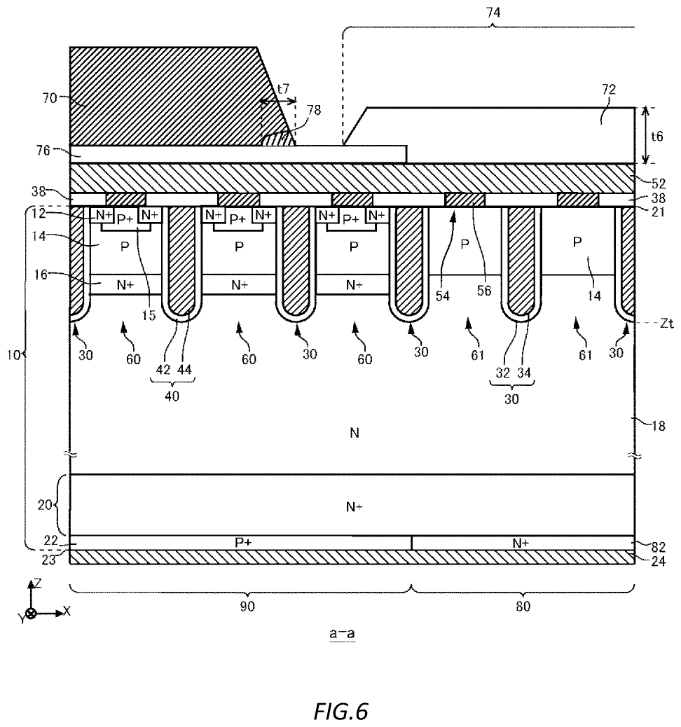

FIG. 6 shows another example of the cross section taken along a-a in FIG. 1. The cross section taken along a-a of the present example is different from the cross section taken along a-a represented in FIG. 2A in that a second plated layer 78 is formed between the protective film 70 and the nitride film 76. Descriptions of the other places are omitted because they are the same as those of FIG. 2A.

The semiconductor device 100 of the present example further includes a second plated layer 78 that is provided between the protective film 70 and the nitride film 76 and has a density less than that of the plated layer 72. Density means weight per unit volume. In FIG. 6, the second plated layer is indicated by coarse hatching. In the plated layer forming step S1014, if adhesiveness between the protective film 70 and the nitride film 76 is low, plating solution penetrates between the protective film 70 and the nitride film 76, and therefore a second plated layer 78 having a density less than that of the plated layer 72 is formed.

Because the adhesiveness between the protective film 70 and the nitride film 76 improves by performing the annealing treatment in the annealing treatment step S1012 to reduce penetration of the plating solution, growing of the second plated layer 78 can be suppressed. As a duration of a plating process in the plated layer forming step S1014 becomes longer, the thickness t6 of the plated layer 72 becomes greater, and similarly, it is considered that the second plated layer 78 grows. Then, as a degree of growth suppressing, a ratio of the thickness of the plated layer 72 to the length of the second plated layer 78 may be used. That is, a length of the second plated layer 78 in a direction in which the protective film 70 and the plated layer 72 are connected in a plane that is parallel to the upper surface 21 of the semiconductor substrate 10 (an X axis direction in the cross section taken along a-a) is referred to as t7. The thickness t7 may be less than or equal to one half of the thickness t6. The thickness t7 may be 30% or less, 20% or less, or 10% or less of the thickness t6.

While the present invention has been described by way of the embodiments, the technical scope of the present invention is not limited to the above-described embodiments. It is apparent to persons skilled in the art that various alterations or improvements can be made to the above-described embodiments. It is also apparent from the described scope of the claims that the embodiments added with such alterations or improvements can be included the technical scope of the present invention.

The operations, procedures, steps, stages, or the like of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A semiconductor device comprising:
a semiconductor substrate having an upper surface;
a first electrode that is provided on or above the upper surface of the semiconductor substrate;
a protective film that is provided on or above the first electrode;
a plated layer that is provided on or above the first electrode and has a non-superposed portion that is not overlapped with the protective film in a top view; and
a nitride film that is continuously provided from a part between the protective film and the first electrode to a part between the non-superposed portion and the first electrode, wherein
a thickness of the plated layer that is positioned upper than the nitride film is greater than a thickness of the nitride film.

2. The semiconductor device according to claim 1, wherein
the nitride film and the plated layer are in contact with each other.

3. The semiconductor device according to claim 1, wherein
the nitride film and the first electrode are in contact with each other.

4. The semiconductor device according to claim 1, wherein
the protective film and the plated layer are in contact with each other.

5. The semiconductor device according to claim 1, wherein
the protective film and the plated layer are apart from each other.

6. The semiconductor device according to claim 1, wherein
in a top view, a first length of a portion in which the nitride film and the plated layer are overlapped, the first length taken in a direction that is perpendicular to an end side of the plated layer, is 1 μm or more.

7. The semiconductor device according to claim 6, wherein
in a top view, the first length is 2 μm or more.

8. The semiconductor device according to claim 7, wherein
in a top view, the first length is 4 μm or less.

9. The semiconductor device according to claim 1, wherein
in the nitride film, a portion that protrudes toward a side of the plated layer from the protective film is 3 μm or more and 7 μm or less.

10. The semiconductor device according to claim 1, wherein
a thickness of the plated layer is greater than a thickness of the protective film.

11. The semiconductor device according to claim 1, further comprising
a second plated layer that is provided between the protective film and the nitride film and having a density less than that of the plated layer, wherein
a length of the second plated layer in a direction in which the protective film and the plated layer are connected in a plane that is parallel to the upper surface of the semiconductor substrate is less than or equal to one half of a thickness of the plated layer.

12. A manufacturing method of a semiconductor device comprising a semiconductor substrate including a first electrode on or above an upper surface thereof, wherein the method comprises:
forming a nitride film on a part of the first electrode;
forming a protective film on or above a part of the nitride film;
an annealing treatment on the nitride film and the protective film; and
after the annealing treatment, forming a plated layer on or above a part of the first electrode that is not covered by the nitride film and on or above a part of the nitride film.

13. The manufacturing method of the semiconductor device according to claim 12, wherein
a temperature of the annealing treatment is 300° C. or more and 400° C. or less.

14. The manufacturing method of the semiconductor device according to claim 12, wherein
a duration of the annealing treatment is 30 minutes or more and one hour or less.

15. The semiconductor device according to claim 2, further comprising
a second plated layer that is provided between the protective film and the nitride film and having a density less than that of the plated layer, wherein
a length of the second plated layer in a direction in which the protective film and the plated layer are connected in a plane that is parallel to the upper surface of the semiconductor substrate is less than or equal to one half of a thickness of the plated layer.

16. The semiconductor device according to claim 3, further comprising
a second plated layer that is provided between the protective film and the nitride film and having a density less than that of the plated layer, wherein
a length of the second plated layer in a direction in which the protective film and the plated layer are connected in a plane that is parallel to the upper surface of the semiconductor substrate is less than or equal to one half of a thickness of the plated layer.

17. The semiconductor device according to claim 4, further comprising
a second plated layer that is provided between the protective film and the nitride film and having a density less than that of the plated layer, wherein
a length of the second plated layer in a direction in which the protective film and the plated layer are connected in a plane that is parallel to the upper surface of the semiconductor substrate is less than or equal to one half of a thickness of the plated layer.

18. The semiconductor device according to claim 5, further comprising
a second plated layer that is provided between the protective film and the nitride film and having a density less than that of the plated layer, wherein
a length of the second plated layer in a direction in which the protective film and the plated layer are connected in a plane that is parallel to the upper surface of the semiconductor substrate is less than or equal to one half of a thickness of the plated layer.

19. The semiconductor device according to claim 6, further comprising
a second plated layer that is provided between the protective film and the nitride film and having a density less than that of the plated layer, wherein
a length of the second plated layer in a direction in which the protective film and the plated layer are connected in a plane that is parallel to the upper surface of the semiconductor substrate is less than or equal to one half of a thickness of the plated layer.

20. The semiconductor device according to claim 7, further comprising
a second plated layer that is provided between the protective film and the nitride film and having a density less than that of the plated layer, wherein
a length of the second plated layer in a direction in which the protective film and the plated layer are connected in a plane that is parallel to the upper surface of the semiconductor substrate is less than or equal to one half of a thickness of the plated layer.
